(19) United States
(12) Patent Application Publication
(10) Pub. No.: US 2006/0062930 A1
(43) Pub. Date: Mar. 23, 2006

(54) Plasma-assisted carburizing

(76) Inventors: Devendra Kumar, Rochester Hills, MI (US); Satyendra Kumar, Troy, MI (US); Michael L Dougherty SR., Rochester Hills, MI (US)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 10/513,394

(22) PCT Filed: May 7, 2003
(86) PCT No.: PCT/US03/14052

§ 371 Date: Aug. 5, 2005

Related U.S. Application Data
(60) Provisional application No. 60/378,693, filed on May 8, 2002.
(60) Provisional application No. 60/430,677, filed on Dec. 4, 2002.
(60) Provisional application No. 60/435,278, filed on Dec. 23, 2002.

(51) Int. Cl. H05H 1/24; C23C 16/00

(52) U.S. Cl. 427/569; 118/723 R

(57) ABSTRACT

A system and method of carburizing a surface region of an object includes subjecting a gas to electromagnetic radiation, generated from a radiation source (52), in the presence of a plasma catalyst (70) to initiate a plasma containing carbon. The method also includes exposing the surface region of the object to the plasma for a period of time sufficient to transfer at least some of the carbon from the plasma to the object through the first surface region.

### CROSS-REFERENCE TO RELATED APPLICATIONS

Priority is claimed to U.S. Provisional Patent Application No. 60/378,693, filed May 8, 2002, No. 60/430,677, filed Dec. 4, 2002, and No. 60/435,278, filed Dec. 23, 2002, all of which are fully incorporated herein by reference.

### FIELD OF THE INVENTION

This invention relates to systems and methods of carburizing. More specifically, the invention relates to systems and methods for igniting, modulating, and sustaining plasmas in gases using plasma catalysts and for using the plasmas in a carburizing process.

### BACKGROUND

Carburizing is a widely known surface hardening process. The process involves diffusing carbon into a low carbon steel alloy to form a high carbon steel surface. The diffused carbon normally reacts with alloys of the steel to enhance the hardness of the steel surface. Carburizing may result in a component that has a high surface hardness and a softer core. Carburizing, therefore, may be especially useful for treating high wear components such as gears and shafts. Enhanced surface hardness may provide suitable resistance to frictional and impact wear without sacrificing desirable properties of the bulk material.

The depth of diffusion of carbon into the steel may be controlled by the temperature of the component and time of exposure to an environment containing carbon. Most often, a part to be carburized is heated in a furnace to a desired carburizing temperature in an environment including carbon. After carburizing, the work may be either slow-cooled for later quench hardening, or quenched directly into various gaseous or liquid quenches.

While known methods of carburizing may achieve acceptable surface hardness levels, these methods include several disadvantages. For example, a part may be carburized in an atmospheric carburizing oven, however, small or thin features of the part will generally heat faster than the remainder of the surface of the part. As a result, these features may exhibit a higher hardness than the rest of the part. Moreover, atmospheric carburizing ovens are generally slow and lack the ability to precisely control the temperature of the part.

Carburizing may also be performed in a vacuum furnace. In this arrangement, the part may be placed in a vacuum chamber, which is then evacuated. The part is heated to a desired temperature and a carburizing gas may be supplied to the vacuum chamber. While this method may produce surfaces with uniform hardness values, it is still costly and time-consuming to establish and maintain the required vacuum environment during a carburizing process.

Carburizing has also been performed by exposing the part to a plasma containing carbon. While plasma carburizing methods may offer potential increases in heating rates over traditional furnace carburizing methods, these plasma carburizing methods involve the use of costly vacuum equipment to provide the necessary vacuum environments. Further, generation of the carburizing plasma usually requires the application of several hundred volts of DC between the work piece and the cathode (e.g., chamber).

The present invention solves one or more of the problems associated with known carburizing systems and/or methods.

### SUMMARY OF THE INVENTION

One aspect of the invention includes a plasma-assisted method of carburizing a first surface region of an object. The method includes initiating a carburizing plasma by subjecting a gas to microwave radiation in the presence of a plasma catalyst, where the plasma contains carbon, and exposing the first surface region of the object to the plasma for a period of time sufficient to transfer at least some of the carbon from the plasma to the object through the first surface region.

A second aspect of the invention includes a system for plasma-assisted carburizing an object. The system includes a plasma catalyst, a vessel in which a cavity is formed and in which a plasma can be ignited by subjecting a gas to electromagnetic radiation (e.g., microwave radiation) in the presence of the plasma catalyst in the cavity, and an electromagnetic radiation source connected to the cavity for directing radiation into the cavity.

A number of plasma catalysts are also provided for plasma-assisted carburizing processes consistent with this invention.

### BRIEF DESCRIPTION OF THE DRAWINGS

Further aspects of the invention will be apparent upon consideration of the following detailed description, taken in conjunction with the accompanying drawings, in which like reference characters refer to like parts throughout, and in which:

FIG. 1 shows a schematic diagram of an illustrative carburizing plasma system consistent with this invention;

FIG. 1A shows an illustrative embodiment of a portion of a carburizing plasma system for adding a powder plasma catalyst to a plasma cavity for igniting, modulating, or sustaining a plasma in a cavity consistent with this invention;

FIG. 2 shows an illustrative plasma catalyst fiber with at least one component having a concentration gradient along its length consistent with this invention;

FIG. 3 shows an illustrative plasma catalyst fiber with multiple components at a ratio that varies along its length consistent with this invention;

FIG. 4 shows another illustrative plasma catalyst fiber that includes a core under layer and a coating consistent with this invention;

FIG. 5 shows a cross-sectional view of the plasma catalyst fiber of FIG. 4, taken from line 5-5 of FIG. 4, consistent with this invention;

FIG. 6 shows an illustrative embodiment of another portion of a plasma system including an elongated plasma catalyst that extends through ignition port consistent with this invention;

FIG. 7 shows an illustrative embodiment of an elongated plasma catalyst that can be used in the system of FIG. 6 consistent with this invention;

FIG. 8 shows another illustrative embodiment of an elongated plasma catalyst that can be used in the system of FIG. 6 consistent with this invention; and

FIG. 9 shows an illustrative embodiment of a portion of a plasma system for directing radiation into a plasma chamber consistent with this invention.

### DETAILED DESCRIPTION OF THE INVENTION

Methods and apparatus for plasma-assisted carburizing can be provided consistent with this invention. The carburizing plasmas can be ignited, as well as modulated and sustained, with a plasma catalyst consistent with this invention.

The following commonly owned, concurrently filed U.S. patent applications are hereby incorporated by reference in their entireties: U.S. patent application Ser. No. 10/______ (Atty. Docket No. 1837.0008), Ser. No. 10/______ (Atty. Docket No. 1837.0009), Ser. No. 10/______ (Atty. Docket No. 1837.0010), Ser. No. 10/______, (Atty. Docket No. 1837.0012), Ser. No. 10/______ (Atty. Docket No. 1837.0013), Ser. No. 10/______ (Atty. Docket No. 1837.0015), Ser. No. 10/______ (Atty. Docket No. 1837.0016), Ser. No. 10/______ (Atty. Docket No. 1837.0017), Ser. No. 10/______ (Atty. Docket No. 1837.0018), Ser. No. 10/______ (Atty. Docket No. 1837.0020), Ser. No. 10/______ (Atty. Docket No. 1837.0021), Ser. No. 10/______ (Atty. Docket No. 1837.0023), Ser. No. 10/______ (Atty. Docket No. 1837.0024), Ser. No. 10/______ (Atty. Docket No. 1837.0025), Ser. No. 10/______ (Atty. Docket No. 1837.0026), Ser. No. 10/______ (Atty. Docket No. 1837.0027), Ser. No. 10/______ (Atty. Docket No. 1837.0028), Ser. No. 10/______ (Atty. Docket No. 1837.0029), Ser. No. 10/______ (Atty. Docket No. 1837.0030), Ser. No. 10/______ (Atty. Docket No. 1837.0032), and Ser. No. 10/______ (Atty. Docket No. 1837.0033).

Illustrative Plasma System

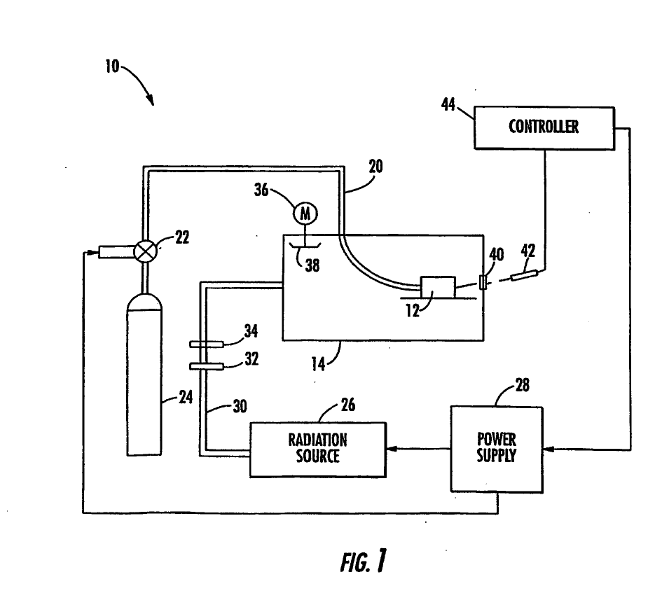

FIG. 1 illustrates an exemplary carburizing system 10 consistent with one aspect of this invention. In this embodiment, cavity 12 is formed in a vessel that is positioned inside radiation chamber (i.e., applicator) 14. In another embodiment (not shown), vessel 12 and radiation chamber 14 are the same, thereby eliminating the need for two separate components. The vessel in which cavity 12 is formed can include one or more radiation-transmissive (e.g., microwave-transmissive) insulating layers to improve its thermal insulation properties without significantly shielding cavity 12 from the radiation.

In one embodiment, cavity 12 is formed in a vessel made of ceramic. Due to the extremely high temperatures that can be achieved with plasmas consistent with this invention, a ceramic capable of operating at a temperature greater than about 2,000 degrees Fahrenheit, such as about 3,000 degrees Fahrenheit, can be used. The ceramic material can include, by weight, 29.8% silica, 68.2% alumina, 0.4% ferric oxide, 1% titania, 0.1% lime, 0.1% magnesia, 0.4% alkalies, which is sold under Model No. LW-30 by New Castle Refractories Company, of New Castle, Pa. It will be appreciated by those of ordinary skill in the art, however, that other materials, such as quartz, and those different from the one described above, can also be used consistent with the invention.

In one successful experiment, a plasma was formed in a partially open cavity inside a first brick and topped with a second brick. The cavity had dimensions of about 2 inches by about 2 inches by about 1.5 inches. At least two holes were also provided in the brick in communication with the cavity: one for viewing the plasma and at least one hole for providing a gas from which the plasma can be formed. The size and shape of the cavity can depend on the desired plasma process being performed. Also, the cavity should at least be configured to prevent the plasma from rising/floating away from the primary processing region.

Cavity 12 can be connected to one or more gas sources 24 (e.g., a source of argon, nitrogen, hydrogen, xenon, krypton) by line 20 and control valve 22, which may be powered by power supply 28. Line 20 may be any channel capable of conveying the gas but narrow enough to prevent significant microwave radiation leakage. For example, line 20 may be tubing (e.g., having a diameter between about 1/16 inch and about ¼ inch, such as about ⅛″). Also, if desired, a vacuum pump can be connected to the chamber to remove any undesirable fumes that may be generated during plasma processing. In one embodiment, gas can flow in and/or out of cavity 12 through one or more gaps in a multi-part vessel. Thus, gas ports consistent with this invention need not be distinct holes and can take on other forms as well, such as many small distributed holes.

A radiation leak detector (not shown) was installed near source 26 and waveguide 30 and connected to a safety interlock system to automatically turn off the radiation (e.g., microwave) power supply if a leak above a predefined safety limit, such as one specified by the FCC and/or OSHA (e.g., 5 mW/cm²), was detected.

Radiation source 26, which may be powered by electrical power supply 28, directs radiation energy into chamber 14 through one or more waveguides 30. It will be appreciated by those of ordinary skill in the art that source 26 can be connected directly to chamber 14 or cavity 12, thereby eliminating waveguide 30. The radiation energy entering cavity 12 is used to ignite a plasma within the cavity. This plasma can be substantially sustained and confined to the cavity by coupling additional radiation, such as microwave radiation, with the catalyst.

Radiation energy can be supplied through circulator 32 and tuner 34 (e.g., 3-stub tuner). Tuner 34 can be used to minimize the reflected power as a function of changing ignition or processing conditions, especially before the plasma has formed because microwave power, for example, will be strongly absorbed by the plasma.

As explained more fully below, the location of radiation-transmissive cavity 12 in chamber 14 may not be critical if chamber 14 supports multiple modes, and especially when the modes are continually or periodically mixed. For example, motor 36 can be connected to mode-mixer 38 for making the time-averaged radiation energy distribution substantially uniform throughout chamber 14. Furthermore, window 40 (e.g., a quartz window) can be disposed in one wall of chamber 14 adjacent to cavity 12, permitting temperature sensor 42 (e.g., an optical pyrometer) to be used to view a process inside cavity 12. In one embodiment, the optical pyrometer has a voltage output that can vary with temperature to within a certain tracking range.

Sensor 42 can develop output signals as a function of the temperature or any other monitorable condition associated with a work piece (not shown) within cavity 12 and provide the signals to controller 44. Dual temperature sensing and heating, as well as automated cooling rate and gas flow controls can also be used. Controller 44 in turn can be used to control operation of power supply 28, which can have one output connected to radiation source 26 as described above and another output connected to valve 22 to control gas flow into radiation cavity 12.

The invention has been practiced with equal success employing microwave sources at both 915 MHz and 2.45 GHz provided by Communications and Power Industries (CPI), although radiation having any frequency less than about 333 GHz can be used. The 2.45 GHz system provided continuously variable microwave power from about 0.5 kilowatts to about 5.0 kilowatts. A 3-stub tuner allowed impedance matching for maximum power transfer and a dual directional coupler (not shown in FIG. 1) was used to measure forward and reflected powers.

As mentioned above, radiation having any frequency less than about 333 GHz can be used consistent with this invention. For example, frequencies, such as power line frequencies (about 50 Hz to about 60 Hz), can be used, although the pressure of the gas from which the plasma is formed may be lowered to assist with plasma ignition. Also, any radio frequency or microwave frequency can be used consistent with this invention, including frequencies greater than about 100 kHz. In most cases, the gas pressure for such relatively high frequencies need not be lowered to ignite, modulate, or sustain a plasma, thereby enabling many plasma-processes to occur at atmospheric pressures and above.

The equipment was computer controlled using LabView 6i software, which provided real-time temperature monitoring and microwave power control. Noise was reduced by using shift registers to generate sliding averages of suitable number of data points. Also, to include speed and computational efficiency, the number of stored data points in the buffer array were limited by using shift registers and buffer sizing. The pyrometer measured the temperature of a sensitive area of about 1 cm², which was used to calculate an average temperature. The pyrometer sensed radiant intensities at two wavelengths and fit those intensities using Planck's law to determine the temperature. It will be appreciated, however, that other devices and methods for monitoring and controlling temperature are also available and can be used consistent with this invention. Control software that can be used consistent with this invention is described, for example, in commonly owned, concurrently filed U.S. patent application Ser. No. 10/______ (Attorney Docket No. 1837.0033), which is hereby incorporated by reference in its entirety.

Chamber 14 had several glass-covered viewing ports with microwave shields and one quartz window for pyrometer access. Several ports for connection to a vacuum pump and a gas source were also provided, although not necessarily used.

System 10 also included an optional closed-loop deionized water cooling system (not shown) with an external heat exchanger cooled by tap water. During operation, the deionized water first cooled the magnetron, then the load-dump in the circulator (used to protect the magnetron), and finally the radiation chamber through water channels welded on the outer surface of the chamber.

Plasma Catalysts

A plasma catalyst consistent with this invention can include one or more different materials and may be either passive or active. A plasma catalyst can be used, among other things, to ignite, modulate, and/or sustain a plasma at a gas pressure that is less than, equal to, or greater than atmospheric pressure.

One method of forming a plasma consistent with this invention can include subjecting a gas in a cavity to electromagnetic radiation having a frequency less than about 333 GHz in the presence of a passive plasma catalyst. A passive plasma catalyst consistent with this invention can include any object capable inducing a plasma by deforming a local electric field (e.g., an electromagnetic field) consistent with this invention, without necessarily adding additional energy through the catalyst, such as by applying an electric voltage to create a spark.

A passive plasma catalyst consistent with this invention can, for example, be a nano-particle or a nano-tube. As used herein, the term “nano-particle” can include any particle having a maximum physical dimension less than about 100 nm that is at least electrically semi-conductive. Also, both single-walled and multi-walled carbon nanotubes, doped and undoped, can be particularly effective for igniting plasmas consistent with this invention because of their exceptional electrical conductivity and elongated shape. The nanotubes can have any convenient length and can be a powder fixed to a substrate. If fixed, the nanotubes can be oriented randomly on the surface of the substrate or fixed to the substrate (e.g., at some predetermined orientation) while the plasma is ignited or sustained.

A passive plasma catalyst consistent with this invention can also be, for example, a powder and need not comprise nano-particles or nano-tubes. It can be formed, for example, from fibers, dust particles, flakes, sheets, etc. When in powder form, the catalyst can be suspended, at least temporarily, in a gas. By suspending the powder in the gas, the powder can be quickly dispersed throughout the cavity and more easily consumed, if desired.

In one embodiment, the powder catalyst can be carried into the carburizing cavity and at least temporarily suspended with a carrier gas. The carrier gas can be the same or different from the gas that forms the plasma. Also, the powder can be added to the gas prior to being introduced to the cavity. For example, as shown in FIG. 1A, radiation source 52 can supply radiation to cavity 55, in which plasma cavity 60 (in which carburizing takes place) is placed. Powder source 65 provides catalytic powder 70 into gas stream 75. In an alternative embodiment, powder 70 can be first added to cavity 60 in bulk (e.g., in a pile) and then distributed in the cavity in any number of ways, including flowing a gas through or over the bulk powder. In addition, the powder can be added to the gas for igniting, modulating, or sustaining a plasma by moving, conveying, drizzling, sprinkling, blowing, or otherwise feeding the powder into or within the cavity.

In one experiment, a plasma was ignited in a cavity by placing a pile of carbon fiber powder in a copper pipe that extended into the cavity. Although sufficient radiation was directed into the cavity, the copper pipe shielded the powder from the radiation and no plasma ignition took place. However, once a carrier gas began flowing through the pipe, forcing the powder out of the pipe and into the cavity, and thereby subjecting the powder to the radiation, a plasma was nearly instantaneously ignited in the cavity.

A powder plasma catalyst consistent with this invention can be substantially non-combustible, thus it need not contain oxygen or bum in the presence of oxygen. Thus, as mentioned above, the catalyst can include a metal, carbon, a carbon-based alloy, a carbon-based composite, an electrically conductive polymer, a conductive silicone elastomer, a polymer nanocomposite, an organic-inorganic composite, and any combination thereof.

Also, powder catalysts can be substantially uniformly distributed in the plasma cavity (e.g., when suspended in a gas), and plasma ignition can be precisely controlled within the cavity. Uniform ignition can be important in certain applications, including those applications requiring brief plasma exposures, such as in the form of one or more bursts. Still, a certain amount of time can be required for a powder catalyst to distribute itself throughout a cavity, especially in complicated, multi-chamber cavities. Therefore, consistent with another aspect of this invention, a powder catalyst can be introduced into the cavity through a plurality of ignition ports to more rapidly obtain a more uniform catalyst distribution therein (see below).

In addition to powder, a passive plasma catalyst consistent with this invention can include, for example, one or more microscopic or macroscopic fibers, sheets, needles, threads, strands, filaments, yams, twines, shavings, slivers, chips, woven fabrics, tape, whiskers, or any combination thereof. In these cases, the plasma catalyst can have at least one portion with one physical dimension substantially larger than another physical dimension. For example, the ratio between at least two orthogonal dimensions can be at least about 1:2, but can be greater than about 1:5, or even greater than about 1:10.

Thus, a passive plasma catalyst can include at least one portion of material that is relatively thin compared to its length. A bundle of catalysts (e.g., fibers) may also be used and can include, for example, a section of graphite tape. In one experiment, a section of tape having approximately thirty thousand strands of graphite fiber, each about 2-3 microns in diameter, was successfully used. The number of fibers in and the length of a bundle are not critical to igniting, modulating, or sustaining the plasma. For example, satisfactory results have been obtained using a section of graphite tape about one-quarter inch long. One type of carbon fiber that has been successfully used consistent with this invention is sold under the trademark Magnamite®, Model No. AS4C-GP3K, by the Hexcel Corporation, of Anderson, S.C. Also, silicon-carbide fibers have been successfully used.

A passive plasma catalyst consistent with another aspect of this invention can include one or more portions that are, for example, substantially spherical, annular, pyramidal, cubic, planar, cylindrical, rectangular or elongated.

The passive plasma catalysts discussed above include at least one material that is at least electrically semi-conductive. In one embodiment, the material can be highly conductive. For example, a passive plasma catalyst consistent with this invention can include a metal, an inorganic material, carbon, a carbon-based alloy, a carbon-based composite, an electrically conductive polymer, a conductive silicone elastomer, a polymer nanocomposite, an organic-inorganic composite, or any combination thereof. Some of the possible inorganic materials that can be included in the plasma catalyst include carbon, silicon carbide, molybdenum, platinum, tantalum, tungsten, and aluminum, although other electrically conductive inorganic materials are believed to work just as well.

In addition to one or more electrically conductive materials, a passive plasma catalyst consistent with this invention can include one or more additives (which need not be electrically conductive). As used herein, the additive can include any material that a user wishes to add to the plasma. For example, in doping semiconductors and other materials, one or more dopants can be added to the plasma through the catalyst. See, e.g., commonly owned, concurrently filed U.S. patent application Ser. No. 10/______ (Attorney Docket No. 1837.0026), which is hereby incorporated by reference in its entirety. The catalyst can include the dopant itself, or it can include a precursor material that, upon decomposition, can form the dopant. Thus, the plasma catalyst can include one or more additives and one or more electrically conductive materials in any desirable ratio, depending on the ultimate desired composition of the plasma and the process using the plasma.

The ratio of the electrically conductive components to the additives in a passive plasma catalyst can vary over time while being consumed. For example, during ignition, the plasma catalyst could desirably include a relatively large percentage of electrically conductive components to improve the ignition conditions. On the other hand, if used while sustaining the plasma, the catalyst could include a relatively large percentage of additives. It will be appreciated by those of ordinary skill in the art that the component ratio of the plasma catalyst used to ignite and sustain the plasma could be the same.

A predetermined ratio profile can be used to simplify many plasma processes. In many conventional plasma processes, the components within the plasma are added as necessary, but such addition normally requires programmable equipment to add the components according to a predetermined schedule. However, consistent with this invention, the ratio of components in the catalyst can be varied, and thus the ratio of components in the plasma itself can be automatically varied. That is, the ratio of components in the plasma at any particular time can depend on which of the catalyst portions is currently being consumed by the plasma. Thus, the catalyst component ratio can be different at different locations within the catalyst. And, the current ratio of components in a plasma can depend on the portions of the catalyst currently and/or previously consumed, especially when the flow rate of a gas passing through the plasma chamber is relatively slow.

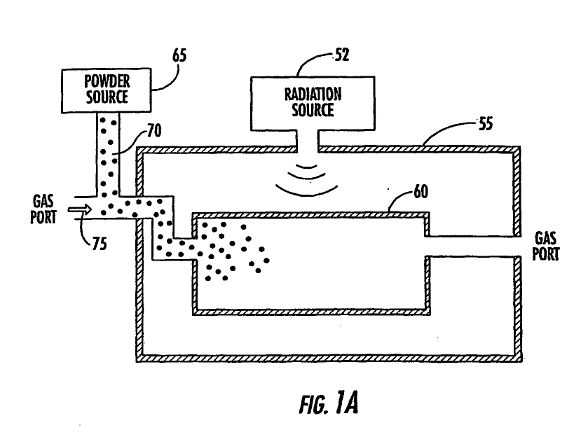

A passive plasma catalyst consistent with this invention can be homogeneous, inhomogeneous, or graded. Also, the plasma catalyst component ratio can vary continuously or discontinuously throughout the catalyst. For example, in FIG. 2, the component ratio can vary smoothly forming a ratio gradient along the length of catalyst 100. Thus, catalyst 100 can include a strand of material that includes a relatively low concentration of one or more components at section 105 and a continuously increasing concentration toward section 110.

Alteratively, as shown in FIG. 3, the ratio can vary discontinuously in each portion of catalyst 120, which includes, for example, alternating sections 125 and 130 having different concentrations. It will be appreciated that catalyst 120 can have more than two section types. Thus, the catalytic component ratio being consumed by the plasma can vary in any predetermined fashion. In one embodiment, when the plasma is monitored and a particular additive is detected, further processing can be automatically commenced or terminated.

Another way to vary the ratio of components in a sustained plasma is by introducing multiple catalysts having different component ratios at different times or different rates. For example, multiple catalysts can be introduced at approximately the same location or at different locations within the cavity. When introduced at different locations, the plasma formed in the cavity can have a component concentration gradient determined by the locations of the various catalysts. Thus, an automated system can include a device by which a consumable plasma catalyst is mechanically inserted before and/or during plasma igniting, modulating, and/or sustaining a plasma.

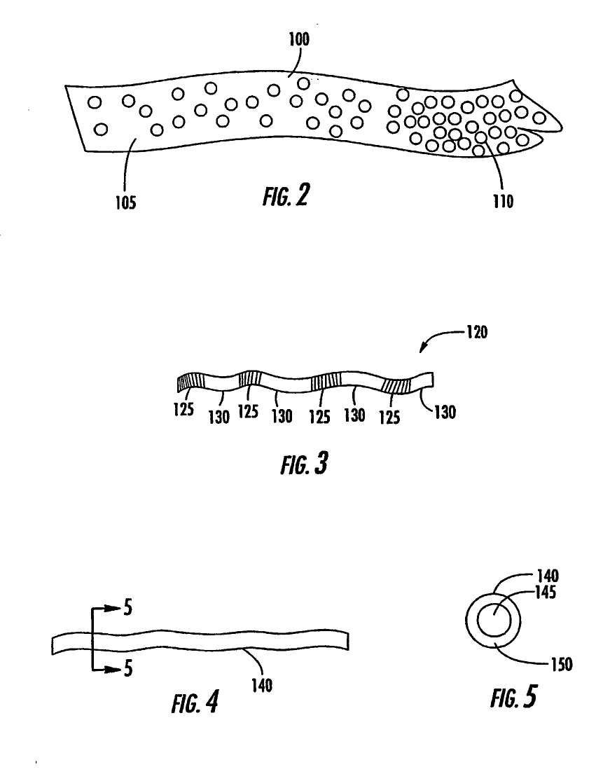

A passive plasma catalyst consistent with this invention can also be coated. In one embodiment, a catalyst can include a substantially non-electrically conductive coating deposited on the surface of a substantially electrically conductive material. Alternatively, the catalyst can include a substantially electrically conductive coating deposited on the surface of a substantially electrically non-conductive material. FIGS. 4 and 5, for example, show fiber 140, which includes under layer 145 and coating 150. In one embodiment, a plasma catalyst including a carbon core is coated with nickel to prevent oxidation of the carbon.

A single plasma catalyst can also include multiple coatings. If the coatings are consumed during contact with the plasma, the coatings could be introduced into the plasma sequentially, from the outer coating to the innermost coating, thereby creating a time-release mechanism. Thus, a coated plasma catalyst can include any number of materials, as long as a portion of the catalyst is at least electrically semi-conductive.

Consistent with another embodiment of this invention, a plasma catalyst can be located entirely within a radiation cavity to substantially reduce or prevent radiation energy leakage via the catalyst. In this way, the plasma catalyst does not electrically or magnetically couple with the vessel containing the cavity or to any electrically conductive object outside the cavity. This prevents sparking at the ignition port and prevents radiation from leaking outside the cavity during the ignition and possibly later if the plasma is sustained. In one embodiment, the catalyst can be located at a tip of a substantially electrically non-conductive extender that extends through an ignition port.

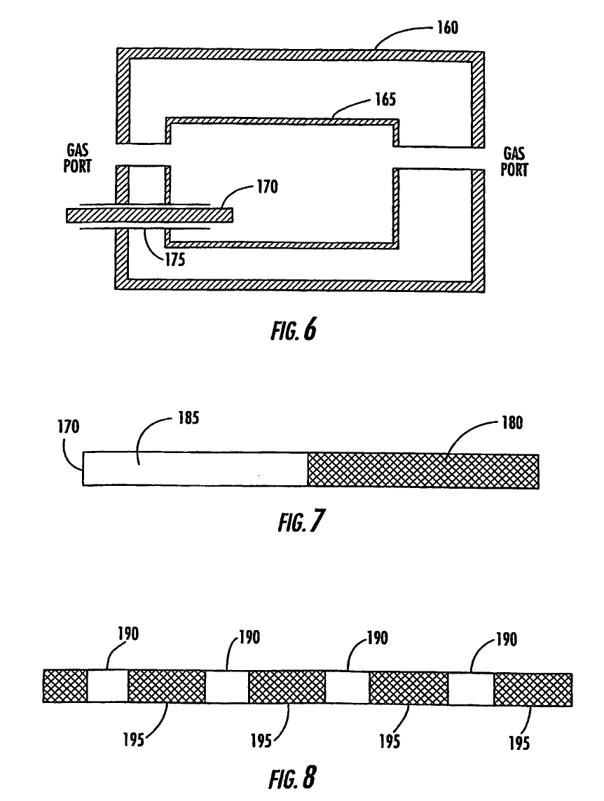

FIG. 6, for example, shows radiation chamber 160 in which plasma cavity 165 is placed. Plasma catalyst 170 can be elongated and can extend through ignition port 175. As shown in FIG. 7, and consistent with this invention, catalyst 170 can include electrically conductive distal portion 180 (which is placed in chamber 160) and electrically non-conductive portion 185 (which is placed substantially outside chamber 160 but can extend into chamber 160). This configuration prevents an electrical connection (e.g., sparking) between distal portion 180 and chamber 160.

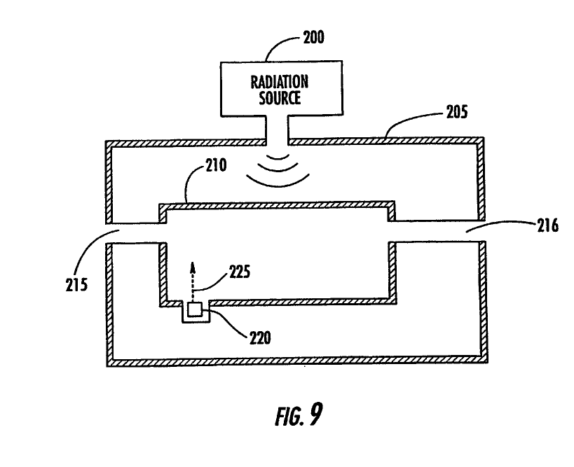

In another embodiment, shown in FIG. 8, the catalyst can be formed from a plurality of electrically conductive segments 190 separated by and mechanically connected to a plurality of electrically non-conductive segments 195. In this embodiment, the catalyst can extend through the ignition port between a point inside the cavity and another point outside the cavity, but the electrically discontinuous profile significantly prevents sparking and energy leakage.

As an alternative to the passive plasma catalysts described above, active plasma catalysts can be used consistent with this invention. A method of forming a carburizing plasma using an active catalyst consistent with this invention includes subjecting a gas in a cavity to electromagnetic radiation having a frequency less than about 333 GHz in the presence of the active plasma catalyst, which generates or includes at least one ionizing particle or ionizing radiation. It will be appreciated that both passive and active plasma catalysts can be used in the same carburizing process.

An active plasma catalyst consistent with this invention can be any particle or high energy wave packet capable of transferring a sufficient amount of energy to a gaseous atom or molecule to remove at least one electron from the gaseous atom or molecule in the presence of electromagnetic radiation. Depending on the source, the ionizing radiation and/or particles can be directed into the cavity in the form of a focused or collimated beam, or they may be sprayed, spewed, sputtered, or otherwise introduced.

For example, FIG. 9 shows radiation source 200 directing radiation into chamber 205. Plasma cavity 210 is positioned inside of chamber 205 and may permit a gas to flow there through via ports 215 and 216. Source 220 directs ionizing particles and/or radiation 225 into cavity 210. Source 220 can be protected, for example, by a metallic screen that allows the ionizing particles to pass through but shields source 220 from radiation. If necessary, source 220 can be water-cooled.

Examples of ionizing radiation and/or particles consistent with this invention can include x-rays, gamma radiation, alpha particles, beta particles, neutrons, protons, and any combination thereof. Thus, an ionizing particle catalyst can be charged (e.g., an ion from an ion source) or uncharged and can be the product of a radioactive fission process. In one embodiment, the vessel in which the plasma cavity is formed could be entirely or partially transmissive to the ionizing particle catalyst. Thus, when a radioactive fission source is located outside the cavity, the source can direct the fission products through the vessel to ignite the plasma. The radioactive fission source can be located inside the radiation chamber to substantially prevent the fission products (i.e., the ionizing particle catalyst) from creating a safety hazard.

In another embodiment, the ionizing particle can be a free electron, but it need not be emitted in a radioactive decay process. For example, the electron can be introduced into the cavity by energizing the electron source (such as a metal), such that the electrons have sufficient energy to escape from the source. The electron source can be located inside the cavity, adjacent the cavity, or even in the cavity wall. It will be appreciated by those of ordinary skill in the art that the any combination of electron sources is possible. A common way to produce electrons is to heat a metal, and these electrons can be further accelerated by applying an electric field.

In addition to electrons, free energetic protons can also be used to catalyze a plasma. In one embodiment, a free proton can be generated by ionizing hydrogen and, optionally, accelerated with an electric field.

Multi-Mode Radiation Cavities

A radiation waveguide, cavity, or chamber can be designed to support or facilitate propagation of at least one electromagnetic radiation mode. As used herein, the term “mode” refers to a particular pattern of any standing or propagating electromagnetic wave that satisfies Maxwell's equations and the applicable boundary conditions (e.g., of the cavity). In a waveguide or cavity, the mode can be any one of the various possible patterns of propagating or standing electromagnetic fields. Each mode is characterized by its frequency and polarization of the electric field and/or the magnetic field vectors. The electromagnetic field pattern of a mode depends on the frequency, refractive indices or dielectric constants, and waveguide or cavity geometry.

A transverse electric (TE) mode is one whose electric field vector is normal to the direction of propagation. Similarly, a transverse magnetic (TM) mode is one whose magnetic field vector is normal to the direction of propagation. A transverse electric and magnetic (TEM) mode is one whose electric and magnetic field vectors are both normal to the direction of propagation. A hollow metallic waveguide does not typically support a normal TEM mode of radiation propagation. Even though radiation appears to travel along the length of a waveguide, it may do so only by reflecting off the inner walls of the waveguide at some angle. Hence, depending upon the propagation mode, the radiation (e.g., microwave radiation) may have either some electric field component or some magnetic field component along the axis of the waveguide (often referred to as the z-axis).

The actual field distribution inside a cavity or waveguide is a superposition of the modes therein. Each of the modes can be identified with one or more subscripts (e.g., TE₁₀ (“tee ee one zero”)). The subscripts normally specify how many “half waves” at the guide wavelength are contained in the x and y directions. It will be appreciated by those skilled in the art that the guide wavelength can be different from the free space wavelength because radiation propagates inside the waveguide by reflecting at some angle from the inner walls of the waveguide. In some cases, a third subscript can be added to define the number of half waves in the standing wave pattern along the z-axis.

For a given radiation frequency, the size of the waveguide can be selected to be small enough so that it can support a single propagation mode. In such a case, the system is called a single-mode system (i.e., a single-mode applicator). The TE₁₀ mode is usually dominant in a rectangular single-mode waveguide.

As the size of the waveguide (or the cavity to which the waveguide is connected) increases, the waveguide or applicator can sometimes support additional higher order modes forming a multi-mode system. When many modes are capable of being supported simultaneously, the system is often referred to as highly moded.

A simple, single-mode system has a field distribution that includes at least one maximum and/or minimum. The magnitude of a maximum largely depends on the amount of radiation supplied to the system. Thus, the field distribution of a single mode system is strongly varying and substantially non-uniform.

Unlike a single-mode cavity, a multi-mode cavity can support several propagation modes simultaneously, which, when superimposed, results in a complex field distribution pattern. In such a pattern, the fields tend to spatially smear and, thus, the field distribution usually does not show the same types of strong minima and maxima field values within the cavity. In addition, as explained more fully below, a mode-mixer can be used to “stir” or “redistribute” modes (e.g., by mechanical movement of a radiation reflector). This redistribution desirably provides a more uniform time-averaged field distribution within the cavity.

A multi-mode cavity consistent with this invention can support at least two modes, and may support many more than two modes. Each mode has a maximum electric field vector. Although there may be two or more modes, one mode may be dominant and may have a maximum electric field vector magnitude that is larger than the other modes. As used herein, a multi-mode cavity may be any cavity in which the ratio between the first and second mode magnitudes is less than about 1:10, or less than about 1:5, or even less than about 1:2. It will be appreciated by those of ordinary skill in the art that the smaller the ratio, the more distributed the electric field energy between the modes, and hence the more distributed the radiation energy is in the cavity.

The distribution of plasma within a processing cavity may strongly depend on the distribution of the applied radiation. For example, in a pure single mode system, there may only be a single location at which the electric field is a maximum. Therefore, a strong plasma may only form at that single location. In many applications, such a strongly localized plasma could undesirably lead to non-uniform plasma treatment or heating (i.e., localized overheating and underheating).

Whether or not a single or multi-mode cavity is used consistent with this invention, it will be appreciated by those of ordinary skill in the art that the cavity in which the plasma is formed can be completely closed or partially open. For example, in certain applications, such as in plasma-assisted furnaces, the cavity could be entirely closed. See, for example, commonly owned, concurrently filed U.S. patent application Ser. No. 10/______ (Attorney Docket No. 1837.0020), which is fully incorporated herein by reference. In other applications, however, it may be desirable to flow a gas through the cavity, and therefore the cavity must be open to some degree. In this way, the flow, type, and pressure of the flowing gas can be varied over time. This may be desirable because certain gases, such as argon, which facilitate formation of plasma, are easier to ignite but may not be needed during subsequent plasma processing.

Mode-Mixing

For many carburizing applications, a cavity containing a substantially uniform plasma is desirable. However, because microwave radiation can have a relatively long wavelength (e.g., several tens of centimeters), obtaining a uniform distribution can be difficult to achieve. As a result, consistent with one aspect of this invention, the radiation modes in a multi-mode cavity can be mixed, or redistributed, over a period of time. Because the field distribution within the cavity must satisfy all of the boundary conditions set by the inner surface of the cavity, those field distributions can be changed by changing the position of any portion of that inner surface.

In one embodiment consistent with this invention, a movable reflective surface can be located inside the radiation carburizing cavity. The shape and motion of the reflective surface should, when combined, change the inner surface of the cavity during motion. For example, an “L” shaped metallic object (i.e., “mode-mixer”) when rotated about any axis will change the location or the orientation of the reflective surfaces in the cavity and therefore change the radiation distribution therein. Any other asymmetrically shaped object can also be used (when rotated), but symmetrically shaped objects can also work, as long as the relative motion (e.g., rotation, translation, or a combination of both) causes some change in the location or orientation of the reflective surfaces. In one embodiment, a mode-mixer can be a cylinder that is rotable about an axis that is not the cylinder's longitudinal axis.

Each mode of a multi-mode carburizing cavity may have at least one maximum electric field vector, but each of these vectors could occur periodically across the inner dimension of the cavity. Normally, these maxima are fixed, assuming that the frequency of the radiation does not change. However, by moving a mode-mixer such that it interacts with the radiation, it is possible to move the positions of the maxima. For example, mode-mixer 38 can be used to optimize the field distribution within carburizing cavity 12 such that the plasma ignition conditions and/or the plasma sustaining conditions are optimized. Thus, once a plasma is excited, the position of the mode-mixer can be changed to move the position of the maxima for a uniform time-averaged plasma process (e.g., heating and/or carburizing).

Thus, consistent with this invention, mode-mixing can be useful during plasma ignition. For example, when an electrically conductive fiber is used as a plasma catalyst, it is known that the fiber's orientation can strongly affect the minimum plasma-ignition conditions. It has been reported, for example, that when such a fiber is oriented at an angle that is greater than 60° to the electric field, the catalyst does little to improve, or relax, these conditions. By moving a reflective surface either in or near the carburizing cavity, however, the electric field distribution can be significantly changed.

Mode-mixing can also be achieved by launching the radiation into the applicator chamber through, for example, a rotating waveguide joint that can be mounted inside the applicator chamber. The rotary joint can be mechanically moved (e.g., rotated) to effectively launch the radiation in different directions in the radiation chamber. As a result, a changing field pattern can be generated inside the applicator chamber.

Mode-mixing can also be achieved by launching radiation in the radiation chamber through a flexible waveguide. In one embodiment, the waveguide can be mounted inside the chamber. In another embodiment, the waveguide can extend into the chamber. The position of the end portion of the flexible waveguide can be continually or periodically moved (e.g., bent) in any suitable manner to launch the radiation (e.g., microwave radiation) into the chamber at different directions and/or locations. This movement can also result in mode-mixing and facilitate more uniform plasma processing (e.g., heating) on a time-averaged basis. Alternatively, this movement can be used to optimize the location of a plasma for ignition or other plasma-assisted process.

If the flexible waveguide is rectangular, a simple twisting of the open end of the waveguide will rotate the orientation of the electric and the magnetic field vectors in the radiation inside the applicator chamber. Then, a periodic twisting of the waveguide can result in mode-mixing as well as rotating the electric field, which can be used to assist ignition, modulation, or sustaining of a plasma.

Thus, even if the initial orientation of the catalyst is perpendicular to the electric field, the redirection of the electric field vectors can change the ineffective orientation to a more effective one. Those skilled in the art will appreciate that mode-mixing can be continuous, periodic, or preprogrammed.

In addition to plasma ignition, mode-mixing can be useful during subsequent carburizing and other types of plasma processing to reduce or create (e.g., tune) “hot spots” in the chamber. When a microwave cavity only supports a small number of modes (e.g., less than 5), one or more localized electric field maxima can lead to “hot spots” (e.g., within cavity 12). In one embodiment, these hot spots could be configured to coincide with one or more separate, but simultaneous, plasma ignitions or carburizing events. Thus, the plasma catalyst can be located at one or more of those ignition or subsequent carburizing (e.g., plasma processing) positions.

Multi-Location Ignition

A carburizing plasma can be ignited using multiple plasma catalysts at different locations. In one embodiment, multiple fibers can be used to ignite the plasma at different points within the cavity. Such multi-point ignition can be especially beneficial when a uniform plasma ignition is desired. For example, when a plasma is modulated at a high frequency (i.e., tens of Hertz and higher), or ignited in a relatively large volume, or both, substantially uniform instantaneous striking and restriking of the plasma can be improved. Alternatively, when plasma catalysts are used at multiple points, they can be used to sequentially ignite a carburizing plasma at different locations within a plasma chamber by selectively introducing the catalyst at those different locations. In this way, a carburizing plasma ignition gradient can be controllably formed within the cavity, if desired.

Also, in a multi-mode carburizing cavity, random distribution of the catalyst throughout multiple locations in the cavity increases the likelihood that at least one of the fibers, or any other passive plasma catalyst consistent with this invention, is optimally oriented with the electric field lines. Still, even where the catalyst is not optimally oriented (not substantially aligned with the electric field lines), the ignition conditions are improved.

Furthermore, because a catalytic powder can be suspended in a gas, it is believed that each powder particle may have the effect of being placed at a different physical location within the cavity, thereby improving ignition uniformity within the carburizing cavity.

Dual-Cavity Plasma Igniting/Sustaining

A dual-cavity arrangement can be used to ignite and sustain a plasma consistent with this invention. In one embodiment, a system includes at least a first ignition cavity and a second carburizing cavity in fluid communication with the first cavity. To ignite a plasma, a gas in the first ignition cavity can be subjected to electromagnetic radiation having a frequency less than about 333 GHz, optionally in the presence of a plasma catalyst. In this way, the proximity of the first and second cavities may permit a plasma formed in the first cavity to ignite a carburizing plasma in the second carburizing cavity, which may be sustained with additional electromagnetic radiation.

In one embodiment of this invention, the first cavity can be very small and designed primarily, or solely for plasma ignition. In this way, very little microwave energy may be required to ignite the plasma, permitting easier ignition, especially when a plasma catalyst is used consistent with this invention.

In one embodiment, the first cavity may be a substantially single mode cavity and the second carburizing cavity is a multi-mode cavity. When the first ignition cavity only supports a single mode, the electric field distribution may strongly vary within the cavity, forming one or more precisely located electric field maxima. Such maxima are normally the first locations at which plasmas ignite, making them ideal points for placing plasma catalysts. It will be appreciated, however, that when a plasma catalyst is used, it need not be placed in the electric field maximum and, many cases, need not be oriented in any particular direction.

Carburizing Process

Consistent with the invention, there may be provided a method of carburizing an object such that carbon atoms from a source of carbon diffuse into the object and increase an average carbon concentration of the object. The carbon may be diffused either uniformly over the entire surface of an object, or the carbon may be diffused into only one or more surface regions of the object.

In an illustrative embodiment of the invention, a plasma may be initiated, as described above, by subjecting a gas (from gas source 24, for example) to radiation (e.g., microwave radiation) in the presence of a plasma catalyst. As shown in FIG. 1, this plasma initiation may occur within cavity 12, which may be formed in a vessel positioned inside microwave chamber (i.e., applicator) 14. Carbon may be supplied to the initiated plasma by, for example, providing a source of carbon to the plasma. In one embodiment, this source of carbon may be the plasma catalyst. That is, the plasma catalyst may include carbon that is consumed by the plasma through contact with the plasma.

Further, a plasma catalyst useful in one particular embodiment of the invention may include two or more different materials according to a predetermined ratio profile selected for a particular carburizing process. For example, in one embodiment, a first material may be well suited for facilitating plasma ignition, and a second material may serve as a primary source of plasmatized carbon (i.e., free carbon that has been consumed by and incorporated into a plasma). These materials may be included in the plasma catalyst in configurations including those configurations shown in FIGS. 2-5, 7, 8, and any combination thereof.

Additionally, the carbon in the carburizing plasma may be provided by a carbon source other than or in addition to the plasma catalyst. Such a carbon source can provide carbon to the plasma by, for example, contacting the plasma. Examples of sources of carbon that may be provided to the plasma include at least one of a carbon-containing gas, a hydrocarbon gas (e.g., methane, or other), powdered carbon, carbon nanotubes, carbon nanoparticles, carbon fibers, graphite, solid carbon, vaporized carbon (e.g., carbon particles dissociated from a carbon source by methods including, for example, laser ablation), charcoal, coke, amorphous carbon, cast iron, and any combination thereof. These sources of carbon may be present in cavity 12 upon initiation of the plasma, or they may be supplied to cavity 12 to contact the plasma after the plasma has been initiated. If the source of carbon is gaseous, gas source 24 may be configured to supply not only the plasma source gas, but also the carbon source gas (e.g., gas source 24 may be configure with multiple gas containers and multiple valves 22).

The carbon present in the plasma may be diffused into an object during a carburizing process. For example, at least one surface region of the object may be exposed to the plasma for a period of time sufficient to transfer at least some of the plasmatized carbon from the plasma to the object through the first surface region. Through exposure to the plasma, heat is efficiently transferred from the plasma to the object to be carburized such that the temperature of the object may rise at a rate of more than 400° C. per minute. Carburizing may occur at a wide range of temperatures. Higher temperatures, however, may facilitate and/or speed the diffusion process. In one embodiment of the invention, a portion of the carburizing process may be performed at temperatures of between about 600 degrees Celsius and about 1,100 degrees Celsius, or between about 850 degrees Celsius to about 975 degrees Celsius. Alternatively, the entire process can occur between these temperatures.

Consistent with one aspect of the invention, carbon from the plasma may diffuse into the object to a diffusion depth of about 0.003 inches to about 0.250 inches. As a result, the carbon content of the object in this diffusion region may be increased. Further, a carburizing process according to the invention may be used to increase the carbon content in any ferrous object, including numerous grades of steel. Non-ferrous materials may also be carburized consistent with this invention. In one embodiment, a steel having an initial carbon content of less than about 0.25% may be effectively carburized.

While the carburizing plasma may be initiated without the use of a plasma catalyst, a plasma catalyst may be used to ignite, modulate, or sustain a plasma in certain embodiments. For example, the presence of a passive or active plasma catalyst consistent with this invention may reduce the radiation energy density needed to initiate a carburizing plasma. This reduction allows a plasma to be generated in a controlled manner with a relatively low amount of radiation energy, which can be useful when sensitive portions of an object are exposed to the carburizing plasma. In one controlled embodiment, the plasma may be initiated using a time-averaged radiation energy (e.g., microwave energy) density below about 10 W/cm³. Further, the carburizing plasma may be initiated using a time-averaged radiation energy density below about 5 W/cm³. Advantageously, these relatively low energy densities can be achieved without vacuum equipment.

Thus, the use of a plasma catalyst may facilitate control over the carburizing plasma and processes using the plasma. Specifically, because plasma can be an efficient absorber of electromagnetic radiation, including microwave radiation, any radiation used to initiate the carburizing plasma may be mostly and immediately absorbed by the carburizing plasma. Therefore, the radiation energy directed into a carburizing cavity is less subject to reflection at the early stages of generating a carburizing plasma. As a result, the use of a plasma catalyst may increase control over the rate of heating of an object exposed to the carburizing plasma, the temperature of the object, and the rate of a particular process using the plasma (e.g., carburizing or other process), as well as decrease the likelihood of strong radiation reflection at the early stage of a carburizing process.

The use of a plasma catalyst may also enable initiation of a carburizing plasma over a broad range of pressures. For example, a carburizing plasma consistent with the invention may be generated not only in vacuum environments, where the total pressure is less than atmospheric pressure, but the presence of a plasma catalyst may aid in initiating a plasma at pressures at or above atmospheric pressure. In one embodiment, a carburizing plasma may be initiated in a cavity from a gaseous environment having an initial pressure level of at least about 760 Torr. Further, the carburizing process consistent with the invention may proceed by exposing an object to a plasma in an environment having a pressure of at least about 760 Torr.

In addition to plasma-assisted carburizing a single surface region of an object, the entire surface region of the object may be carburized. Additionally, one or more separate surface regions on the object may be selectively carburized. Certain surface regions of the object may be effectively masked from the carburizing plasma to substantially prevent exposure of these regions to the plasma. In these regions, substantially no carburizing will occur.

For example, cavity 12 may be configured in such a way as to prevent exposure of certain surface regions of the object to the plasma. As previously discussed, the number or order of modes of the radiation in cavity 12 may depend on the size or configuration of the cavity. The presence of an object to be carburized within cavity 12 may also affect the field distribution in the modes of radiation within the cavity. The boundary conditions for normal incidence of electromagnetic radiation on metallic objects require that the electric field at the surface be zero and the first maxima occur at a distance of a quarter wavelength from the surface of the object. Consequently, if the gap between the surface of the metallic object and the inner wall of the cavity is less than about a quarter wavelength of the radiation, little or no plasma may be sustained in these areas, and the surface regions of the object satisfying this condition may experience little or no carburization. These “masked” surface regions may be provided through positioning of the object within cavity 12, by configuring the walls of cavity 12, or by any other suitable method for controlling the distance between the surface of the object and the cavity walls.

A second method for substantially preventing carburization at a particular surface region of the object may include orienting the object with respect to cavity 12 such that at least a portion of the object is located within the cavity and another portion of the object is located outside of the cavity. The portion within the cavity may be carburized, and the portion located outside the cavity may remain substantially free of carburization.

It will be appreciated by those of ordinary skill in the art that plasma-assisted carburizing consistent with this invention need not occur within a cavity at all. Rather, a carburizing plasma formed in a cavity can be flowed through an aperture and used outside the cavity to carburize an object.

In order to generate or to maintain a substantially uniform time-averaged radiation field distribution within cavity 12, mode mixer 38 may be provided, as shown in FIG. 1. Alternatively, or additionally, the object may be moved with respect to the plasma while being exposed to the plasma. Such motion may provide more uniform exposure of all surface regions of the object to the plasma, which may cause carbon to be diffused into the surface of the object according to a substantially uniform profile. Further, such motion may also help to control heating of the object (e.g., to heat certain areas of the object more rapidly than other areas or to heat the entire surface of the part substantially uniformly).

An electric potential bias may be applied to the object during a plasma-assisted carburization process consistent with the invention. Such a potential bias may facilitate heating of the object by attracting the charged carbon atoms in the carburizing plasma to the object, which may encourage uniform coverage of the plasma over the object. Further, the potential bias may accelerate the charged carbon atoms toward the object, which may also increase the rate of carbon diffusion. The potential bias applied to the object may be, for example, an AC bias, a DC bias, or a pulsed DC bias. The magnitude of the bias may be selected according to a particular application. For example, the magnitude of the voltage may range from 0.1 volts to 100 volts, or even several hundred volts depending on the desired rate of attraction of the ionized species. Further, the bias may be either positive or negative.

In another embodiment consistent with this invention, a method of plasma-assisted carburizing a first surface region of an object may be provided that uses plasma to heat the object and the source of carbon, but the plasma does not necessarily transfer the carbon. In this embodiment, the method can include: (1) initiating a plasma by subjecting a gas in a cavity to electromagnetic radiation having a frequency of less than about 333 GHz in the presence of a plasma catalyst, (2) exposing the first surface region of the object to the plasma for a period of time sufficient to heat the surface, (3) exposing a source of carbon to the plasma for a period of time sufficient to heat the source, wherein the source of carbon is a solid source selected from a group consisting of charcoal, coke, carbon fibers, graphite, amorphous carbon, cast iron, and any combination thereof, and (4) transferring at least some of the carbon from the source to the object through the first surface region. Thus, the carbon can be transferred in the form of a vapor, without the use of a plasma.

In the foregoing described embodiments, various features are grouped together in a single embodiment for purposes of streamlining the disclosure. This method of disclosure is not to be interpreted as reflecting an intention that the claimed invention requires more features than are expressly recited in each claim. Rather, as the following claims reflect, inventive aspects lie in less than all features of a single foregoing disclosed embodiment. Thus, the following claims are hereby incorporated into this Detailed Description of Embodiments, with each claim standing on its own as a separate preferred embodiment of the invention.

We claim:

1. A method of plasma-assisted carburizing a first surface region of an object, the method comprising:
initiating a plasma by subjecting a gas to electromagnetic radiation having a frequency of less than about 333 GHz in the presence of a plasma catalyst, wherein the plasma contains carbon; and
exposing the first surface region of the object to the plasma for a period of time sufficient to transfer at least some of the carbon from the plasma to the object through the first surface region.

2. The method of claim 1, wherein the plasma catalyst includes at least one of a passive catalyst and an active catalyst.

3. The method of claim 1, wherein the plasma catalyst comprises carbon, and wherein the method further comprises adding carbon to the plasma by allowing the plasma to consume the plasma catalyst.

4. The method of claim 3, wherein the plasma catalyst includes at least one of powdered carbon, carbon nanotubes, carbon nanoparticles, carbon fibers, graphite, solid carbon, and any combination thereof.

5. The method of claim 1, wherein the plasma catalyst includes at least two different materials in amounts determined by a predetermined ratio profile.

6. The method of claim 1, wherein the plasma catalyst includes at least one of x-rays, gamma radiation, alpha particles, beta particles, neutrons, protons, and any combination thereof.

7. The method of claim 1, wherein the plasma catalyst includes at least one of electrons and ions.

8. The method of claim 1, wherein the plasma catalyst includes at least one of a metal, carbon, a carbon-based alloy, a carbon-based composite, an electrically conductive polymer, a conductive silicone elastomer, a polymer nanocomposite, an organic-inorganic composite, and any combination thereof.

9. The method of claim 1, wherein the initiating comprises initiating the plasma in a cavity from a gaseous environment having an initial pressure level of at least about 760 Torr.

10. The method of claim 1, wherein the exposing is performed at a pressure of at least about 760 Torr.

11. The method of claim 1, wherein the initiating occurs using a time-averaged microwave radiation energy density below about 10 W/cm³.

12. The method of claim 1, wherein the exposing comprises diffusing the carbon into the object below the first surface region while the first surface region is in contact with the plasma.

13. The method of claim 12, wherein the diffusing occurs up to a depth of between about 0.003 inches and about 0.250 inches.

14. The method of claim 1, wherein the object has a second surface region and wherein the exposing further includes substantially preventing exposure of the second surface region to the plasma.

15. The method of claim 14, further comprising positioning the object within a cavity such that the second surface region is separated from an inner wall of the cavity by a distance of less than about 25% of the wavelength of the microwave radiation.

16. The method of claim 14, further comprising orienting the object with respect to a cavity such that the first surface region is located within the cavity and the second surface region is located outside of the cavity.

17. The method of claim 1, further comprising mode-mixing the electromagnetic radiation.

18. The method of claim 1, wherein the exposing comprises:
supplying the electromagnetic radiation into a cavity; and
supplying the gas into the cavity.

19. The method of claim 1, further comprising applying a DC bias to the object.

20. The method of claim 19, wherein the DC bias is a pulsed DC bias.

21. The method of claim 1, further comprising introducing the carbon into the plasma by supplying a carbon-containing gas to the plasma.

22. The method of claim 1, further comprising adding carbon to the plasma from a source of carbon, wherein the source of carbon is a solid source selected from a group consisting of charcoal, coke, carbon fibers, graphite, amorphous carbon, cast iron, and any combination thereof.

23. The method of claim 1, further comprising introducing the carbon into the plasma by supplying vaporized carbon to the plasma.

24. The method of claim 1, wherein the object comprises steel.

25. The method of claim 24, wherein the steel has an initial carbon content of less than about 0.45%.

26. The method of claim 1, further comprising initially heating at least a portion of the object via the plasma to between about 600° C. and about 1,100° C.

27. The method of claim 1, further comprising heating at least a portion of the object at a rate of at least 400° C. per minute until the at (east a portion reaches a temperature of at least about 600° C.

28. The method of claim 1, further comprising moving the object with respect to the plasma during the exposing.

29. A system for plasma-assisted carburizing an object, the system comprising:
a plasma catalyst;
a vessel in which a cavity is formed and in which a plasma can be ignited by subjecting a gas to electromagnetic radiation having a frequency of less than about 333 GHz in the presence of the plasma catalyst in the cavity; and
an electromagnetic radiation source connected to the cavity for directing radiation into the cavity.

30. The system of claim 29, wherein the plasma catalyst includes at least one of a passive catalyst and an active catalyst.

31. The system of claim 29, further comprising an applicator in which the vessel is located, wherein the applicator comprises a material that is substantially opaque to the radiation.

32. The system of claim 31, wherein the microwave radiation has an energy distribution in the applicator, the system further comprising a microwave mode mixer that can move relative to the applicator to vary the energy distribution.

33. The system of claim 31, wherein the applicator is a multi-mode microwave applicator.

34. The system of claim 29, wherein the plasma catalyst includes at least one of powdered carbon, carbon nanotubes, carbon nanoparticles, carbon fibers, graphite, solid carbon, a metal, a carbon-based alloy, a carbon-based composite, an electrically conductive polymer, a conductive silicone elastomer, a polymer nanocomposite, an organic-inorganic composite, and any combination thereof.

35. The system of claim 34, wherein the plasma catalyst includes at least one carbon fiber.

36. The system of claim 29, wherein the plasma catalyst includes at least two different materials in amounts determined by a predetermined ratio profile.

37. The system of claim 29, wherein the plasma catalyst includes at least one of x-rays, gamma radiation, alpha particles, beta particles, neutrons, protons, and any combination thereof.

38. The system of claim 29, wherein the plasma catalyst includes at least one of electrons and ions.

39. The system of claim 31, further including a source of carbon disposed within the applicator.

40. The system of claim 29, wherein the vessel comprises a material that is transmissive to the radiation.

41. The system of claim 29, wherein the applicator and the cavity are the same.

42. A method of plasma-assisted carburizing a first surface region of an object, the method comprising:
initiating a plasma by subjecting a gas in a cavity to electromagnetic radiation having a frequency of less than about 333 GHz in the presence of a plasma catalyst;
exposing the first surface region of the object to the plasma for a period of time sufficient to heat the surface;
exposing a source of carbon to the plasma for a period of time sufficient to heat the source, wherein the source of carbon is a solid source selected from a group consisting of charcoal, coke, carbon fibers, graphite, amorphous carbon, cast iron, and any combination thereof; and
transferring at least some of the carbon from the source to the object through the first surface region.

43. The method of claim 42, wherein the plasma catalyst includes at least one of powdered carbon, carbon nanotubes, carbon nanoparticles, carbon fibers, graphite, solid carbon, a metal, a carbon-based alloy, a carbon-based composite, an electrically conductive polymer, a conductive silicone elastomer, a polymer nanocomposite, an organic-inorganic composite, and any combination thereof.

44. The method of claim 43, wherein the plasma catalyst includes at least one carbon fiber.

45. The method of claim 42, wherein the plasma catalyst includes at least one of x-rays, gamma radiation, alpha particles, beta particles, neutrons, protons, and any combination thereof.

46. The method of claim 42, wherein the plasma catalyst includes at least one of electrons and ions.

47. The method of claim 42, wherein the transferring does not involve the plasma.

48. The method of claim 47, further comprising placing the source of carbon at a position adjacent to the first surface.
